(19) United States
(12) Patent Application Publication
(10) Pub. No.: US 2009/0127697 A1
(43) Pub. Date: May 21, 2009

(54) Housing with a Cavity for a Mechanically-Sensitive Electronic Component and Method for Production

(76) Inventor: Wolfgang Pahl, Munich (DE)

Correspondence Address: FISH & RICHARDSON PC, P.O. BOX 1022, MINNEAPOLIS, MN, 55440-1022, US

(21) Appl. No.: 12/090,529

(22) PCT Filed: Sep. 29, 2006
(86) PCT No.: PCT/DE2006/001736

§ 371 Date: May 15, 2008

(30) Foreign Application Priority Data
Oct. 20, 2005 (DE) 102005050398.5

(51) Int. Cl. H01L 23/04; H01L 21/00; H01L 21/66; H01L 23/495; H01L 21/02; H01L 21/78

(52) U.S. Cl. 257/698; 438/125; 438/17; 257/E23.045; 257/E21.002; 257/E21.599; 257/E21.531

(57) ABSTRACT

An element includes a hollow space for a mechanically sensitive electrical element. The element includes a first housing part and a second housing part rigidly connected to the first housing part via joint surfaces. The element also includes connection surfaces on a base of a recess in the first housing the first housing part being covered by the second housing part to form an enclosed hollow space.

Mechanically sensitive elements exist which are sensitive both to mass loads and also to twisting and which react to corresponding actions with a change in their element properties. For such elements, hollow-space housings are typically required into which the elements must be inserted and also contacted with low stress.

Mechanically sensitive elements are those, e.g., that have mechanical, moving parts, such as, for example, MEMS (micro-electromechanical system) elements. Elements working with acoustic waves are sensitive to mass loads, because these damp the acoustic waves or can influence their propagation rate or can change the resonance frequency of bulk oscillators. Also, piezoelectric substrates in tension change their electromechanical properties, which has an effect, for example, on the velocity of the acoustic wave and thus on the associated frequency.

Especially undesired is interference in frequency-determining elements that are used for generating a desired frequency, for example, a clock frequency for an IC, and in particular, for a microprocessor. These elements allow only a small fault tolerance, but require high quality, low noise, only minimal aging, low temperature coefficients of the element properties, and high shock resistance. Oscillating crystal, which can fulfill the mentioned requirements in satisfactory ways, can be used as the frequency-determining element. With SAW (Surface Acoustic Wave) and BAW (Bulk Acoustic Wave) elements, low-interference resonators, which react with similar sensitivity relative to mechanical stress, can be created, especially at higher frequencies.

Two-part hollow-space housings are known in which conventionally one chip is bonded, provided with internal wire connections, and closed with a cover or a cap. For materials thermally non-adapted for the element-chip and housing, thermal warping can occur, which partially interferes with the sensitive function of the element.

The task of the present invention is to specify a component with a novel housing for elements that are sensitive to stress and/or contamination, wherein this component is simple to fabricate and allows low-stress installation of sensitive elements.

This task is solved with a component with the features of Claim 1. Advantageous configurations of the invention and also a method for fabricating the component are to be taken from additional claims.

The invention proposes a component with a hollow space, and a mechanically sensitive electrical element, which is arranged in the hollow space and in which a rigid connection between the element and housing is eliminated. Instead, a two-part housing made from first and second housing parts is proposed, at least one of which has a recess for the element into which the element is inserted, and which are connected to each other rigidly by means of mutually fitting joint surfaces. When connection surfaces are provided on the base of the recess, the element has contact surfaces facing forward the connection surfaces. For preventing warping stress, now mountings are provided that are connected to the contact surfaces and the connection surfaces and by means of which the element including a chip is mounted in the hollow space and is connected electrically.

The mountings can be deformed elastically or plastically and are therefore suitable for receiving forces that can be generated on the element due to different thermal expansion of the element chip and housing or due to outer mechanical actions on the housing. A component is obtained, in which at most those forces can act on the chip of the element that can be exerted by the mountings against their deformation. This can be set exactly by means of a suitable construction and dimensioning of the mountings.

Preferably, the attachment points of the mountings are distributed uniformly on both the element and on the housing part, so that forces acting from all directions can be absorbed equally.

The component has the additional advantage that the element chip and housing are completely mechanically decoupled, so that the material selection for the housing and element chip can take place independent of each other. In particular, the materials for the housing can be selected independent of the material of the element chip. Accordingly, a material optimized solely to the housing requirements can be used that provides sufficient mechanical strength, good processing, and optionally hermetic sealing properties. Also, with respect to the two housing parts, no mutual material matching needs to take place with respect to similar or equal thermal expansion, since thermal warping between the two housing parts can now no longer act on the element chip and are therefore not harmful to its proper function.

In one construction, the mountings have a geometric configuration by means of which tensile and compressive stresses can be absorbed elastically or plastically. This can be achieved by mountings that do not run linearly, which are bent or angled once or several times in one or more spatial directions, which have a meander-like profile, or which have suitable slots running longitudinally and/or transversely in a band-shaped material. The mountings can also have a spiral construction with one or more turns. Therefore, it is possible to set or increase the inductance of the mountings or to integrate an inductor into the mountings.

The mountings are preferably constructed from metal, but can also have multiple layers, and optionally non-conductive layers, coatings, or other material reinforcements.

The proposed component has the advantage that standard substrates, for which existing technology is available and which is also optimized in terms of cost, can be used for the housing. The proposed component is especially suitable for accommodating chip elements such as sensors, resonators, or filters in SAW (surface acoustic wave), BAW (bulk acoustic wave), or in MEMS (micro-electromechanical system) construction or quartz oscillators. The component can be constructed as an inertial sensor in which a mechanical natural resonance in the corresponding translational or rotational axis can be set by tuning the chip mass and stiffness of the mountings. It is therefore possible to set this natural resonance outside of the bandwidth to be detected. Thus, the excitation of the natural resonance is made more difficult in the sensor application, and interference by natural oscillations of the sensor can be avoided.

The especially low-stress installation of the element chip in the housing enables applications that react especially sensitively to warping and stress. Therefore, in an especially advantageous way, the element chip can be an oscillator, used as a frequency reference, that operates, preferably encapsulated hermetically in the hollow space, at an operating frequency of more than 500 MHz. In this way, another oscillator can be arranged in the component. The arrangement of a resonator (first element) together with an oscillator circuit (second element) within the same housing has the advantage that high frequency-conducting connections between the resonator and oscillator circuit can be directed along the shortest path without in the meantime leaving the housing. Advantageously, the contacts of the elements are also provided or wired so that minimum conductor lengths are needed for connecting the two elements.

The proposed constructions find advantageous uses in mobile telephones, digital cameras, chip cards, or other devices in which the low-stress, encapsulated element produces special advantages for the corresponding device.

The hanging or floating mounting of the element chip can be achieved with mountings that have, between two areas, a longitudinal extent parallel to the base of one of the housing parts that preferably does not run linearly. Each of the mountings is connected by means of a first area to an electrical connection surface on the base of the first housing part. The second area of the mounting is arranged at a distance from said base and is connected to the contact surfaces of the element. The order of magnitude (especially the thickness) of the mountings can lie in the range of optionally reinforced conductor tracks. In this way, an air gap remains between the base of the housing part and the element. For all of the housing parts, the element has an air gap whose size can be adapted to the expected mechanical load of the element. It is further advantageous to adapt the recess in the one or more housing parts to the base surface of the element such that the smallest possible air gap remains between the periphery of the element and the inner edge of the recess. A small air gap contributes to damping undesired mechanical resonances in the Z-direction, that is, vertical to the connection plane of the two housing parts, due to the flow resistance of the air in the air gap. It is advantageous, for example, to form the cross-sectional surface area of the air gaps parallel to the mentioned connection surface to be smaller than 50 percent of the element surface area, but preferably even smaller than 30 percent.

The connection surfaces on the base of the first housing part are preferably connected by means of plated through-holes with solderable contacts on an outer side of this housing part, wherein these solderable contacts form the outer contacts of the component, e.g., SMT (surface mount technology) contacts. A connection surface can be a separately generated metallization on the base that is arranged directly above a plated through-hole. It is also possible, however, optionally to generate plated through-holes with larger cross-sectional surface area, so that the end surface can be used as the connection surface. It is also possible to widen the area of the mountings contacting the base of the first housing part and to construct it in the form of a connection surface, which can then overlap the plated through-holes opening out from the base of the housing part.

It is advantageous for the housing part to have a multiple-layer configuration with at least one structured metallization plane on the inside. This metallization plane can be used as a wiring plane. In a structured metallization plane, passive elements can also be realized as capacitors, inductors, and resistors. For this purpose, two and more metallization planes, with which the corresponding passive components can be easily realized, are advantageous. With inner metallization planes that are arranged between two dielectric layers, it is also possible to prevent plated through-holes from extending linearly through the entire first housing part, and to replace them by a connection of at least two plated through-holes offset relative to each other in the surface through the different dielectric layers.

As additional passive components connected to the element, the mountings can be constructed as inductors, which is supported by their relatively large longitudinal expansion.

The housing part with the recess can be formed by a base plate and a frame-shaped structure (=frame structure) rising above this plate, wherein the base plate and frame structure can be made from the same or different material. At least the frame structure has, on its top edge, a flat surface on which a second housing part can sit that is similarly flat or flat at least in the area of the joint surface, and thus can close off the recess formed by the frame and base plate into the hollow space.

The frame-shaped structure can also be mounted at a later time onto an essentially flat substrate forming the base of the first housing part. As the mounting process, pressing is suitable, wherein either a polymer material or a paste filled with ceramic and/or metallic particles can be used. It is also possible to generate the structure galvanically. Another possibility exists in generating the frame photolithographically from a resist film and, in particular, from a directly structurable photoresist layer. The resist layer can be applied as varnish through centrifuging, casting, immersing, or spraying. The application of the resist layer as a dry film, for example, through lamination, is also advantageous. In particular, temperature-resistant polymers sealed against diffusion of moisture are suitable for the frame structure. Such materials can be selected preferably from aromatic liquid-crystalline polymers, from so-called high-performance thermoplastics, polycondensates from the class of polyaryl ether ketones, polysulfones, polyphenylene sulfide, polyphenyl ether sulfone, polyether sulfone, polyether ketone, or polyether ether ketone. Mixtures of the named polymers are also suitable. In addition to the high temperature resistance, these are also distinguished by relatively high hardness.

The structuring can take place through phototechnology or laser ablation. Here, a scanning exposure can take place with a radiation source and especially with a laser. It is also advantageous to deposit a non-metallic frame on a substrate forming the base plate of the first housing part and then to form a metallization at least on the area forming the joint surfaces. This has the advantage that with metallic joint surfaces, especially when they are similarly connected to metallic second joint surfaces, especially simple hermetic connections can be fabricated that allow hermetic closure of the hollow space between the base plate, frame, and flat second housing part.

Both the base plate and also the second housing part can include ceramic materials independently of each other, especially ceramic multi-layer plates, such as LTCC (low temperature cofired ceramics) or HTCC (high temperature cofired ceramics), glass, silicon, plastic, and especially a liquid-crystalline polymer, a conductor-plate laminate, or another suitable circuit carrier. For example, an MID molded part (Molded Interconnect Device) is also suitable. The low-stress suspension of the element allows different materials, which can be optimized for the corresponding needs, to be used for the first housing part made from the base plate and frame structure and a cover forming the second housing part. It is advantageous, e.g., to realize the cover from a metal foil or a film coated with metal, in particular, a metal-coated plastic film. This can be connected especially well to a metallic or metal-coated joint surface of the bottom first housing part.

Such a component has good electromagnetic shielding for the element. For further improvement of the shielding, the inside of the frame structure and also an edge region on the base plate within the hollow space in the neighborhood of the frame structure can be metallized. In this way, an otherwise hermetic closure of the hollow space is not negatively affected by a gas-permeable frame material.

The hollow space can also be provided in the second housing part. Because the second housing part requires no further structuring and in particular no plated through-hole, it can be formed as a cap and especially as a metallic cap, which then sits on the joint surface on a preferably flat first housing part or the substrate forming this first housing part. The metallic cap also generates good shielding, which can be reinforced by additional metallization underneath the cap on the first housing part.

The recess formed in a housing part or the wall bordering the recess can also be an integral part of the substrate (base plate). As such, it is produced integrated together with the substrate, especially by applying and structuring additional base plate materials. In the production of a multi-layer ceramic base plate, for example, one or more of the uppermost layers can be pre-formed with the mentioned recess already in the green sheet, with a correspondingly shaped first housing part being formed after lamination and sintering. Corresponding possibilities are also provided for laminate conductor plates. Here, preferably the joint surfaces and also the inner wall and sub-regions of the base surface of the recess can also be metallized.

As a function of the material used in the first and second housing part at the joint surfaces, different methods are provided for connecting the two housing parts. Metallic joint surfaces can be connected by solder, bonding, or welding. Glass solder is suitable for many inorganic materials used on the joint surfaces. Adhesives can be used universally.

Mountings can be used for simultaneous electrical and mechanical bonding of the element to the housing part and the provided mechanical and electrical connection surfaces. However, it is also possible to provide several mountings for the production of one electrically conductive connection, or also to provide mountings that have no electrical connection and are used exclusively for mechanical suspension of the element. In this way, a desired stiffness in relation to the moving mass can be set and used for setting the natural resonance.

In addition, a mechanically rigid connection, which is preferably arranged in the middle of the element and which is limited to a narrow region in terms of surface area, can be provided between the element and base of the first housing part, so that by means of this individual rigid connection, no thermal warping can appear at attachment points far away from each other. This individual rigid connection has the advantage that the mountings must be mechanically less stable and can be constructed so that they counteract deformation with a smaller force than would be the case with a component in which all of the connections between the element and housing part were effected by means of the mountings. Even natural oscillations of the element could be reduced. In this way, even less stress, which could negatively affect the element function, acts on the element.

Below, the invention and the method for producing the component according to the invention will be explained in more detail with reference to embodiments and the associated figures. These are done only schematically and are used simply to illustrate the invention, so that neither absolute nor relative dimensional information is to be inferred from them.

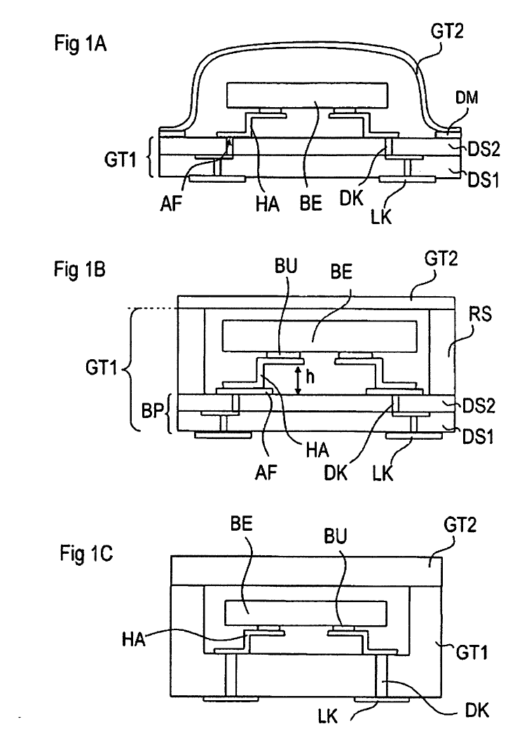

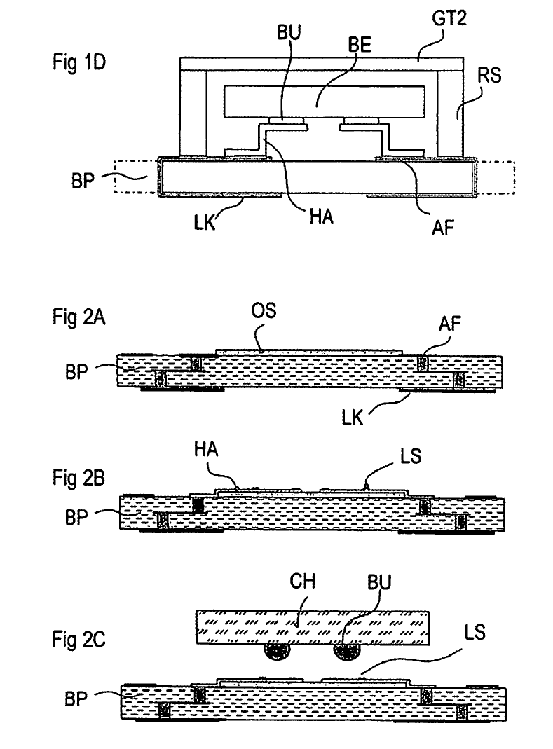

FIG. 1 shows different constructions of components according to the invention.

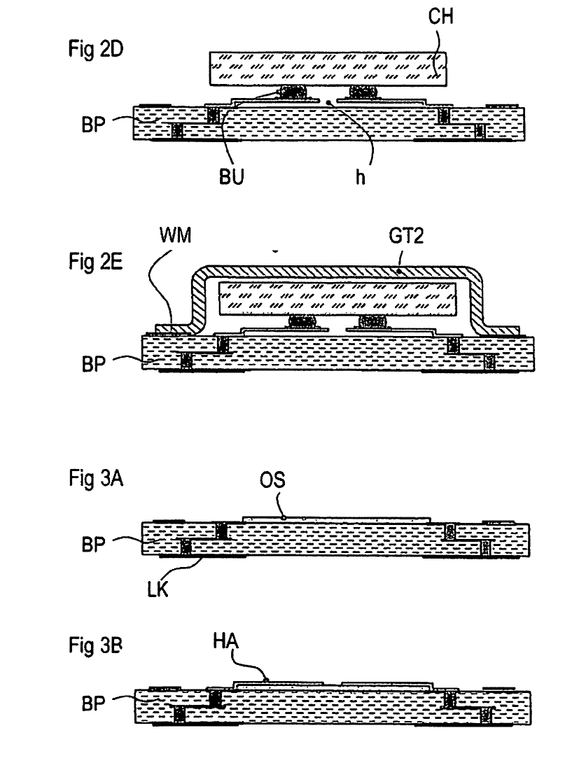

FIG. 2 shows the production of an element according to a first embodiment.

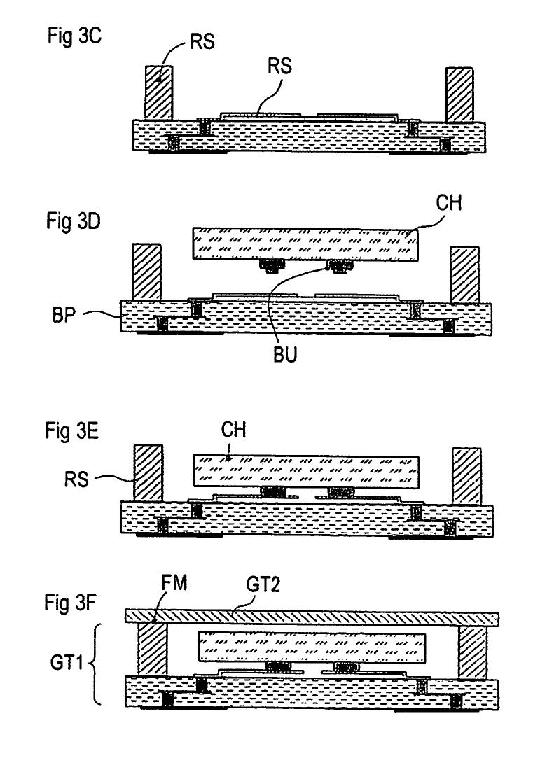

FIG. 3 shows the production of an element according to a second embodiment.

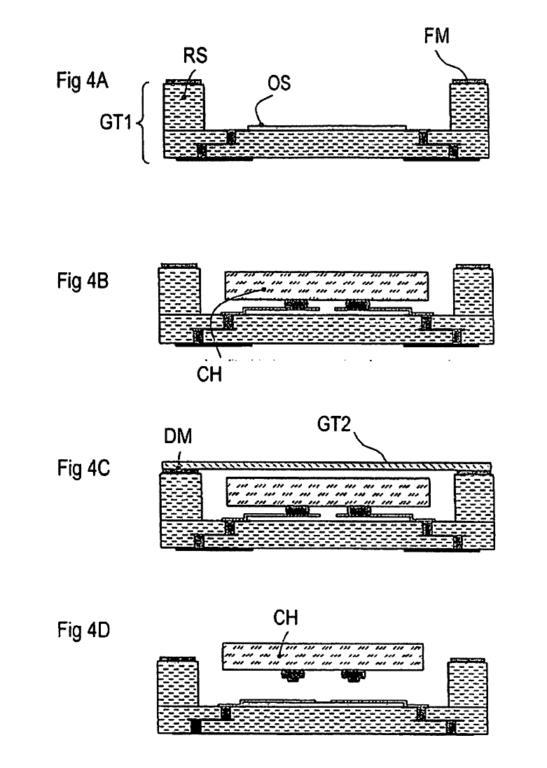

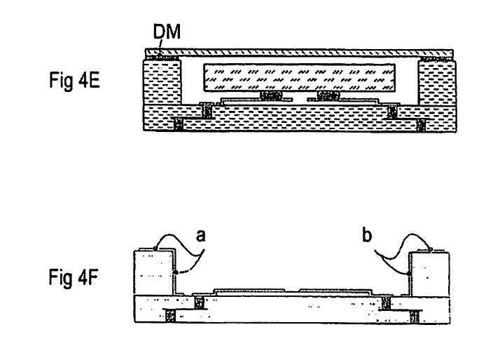

FIG. 4 shows the production of an element according to a third embodiment and

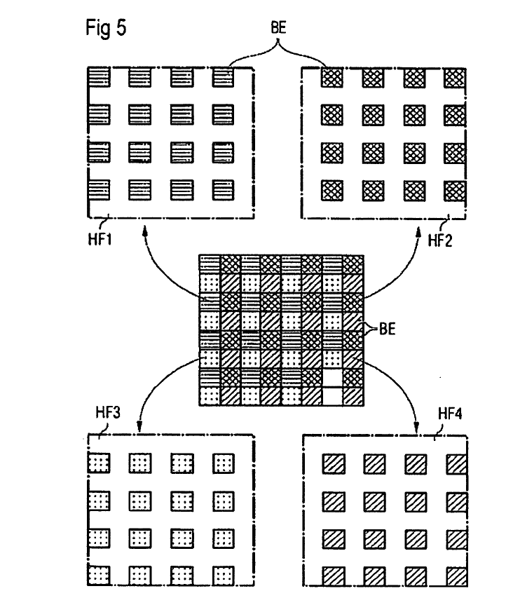

FIG. 5 shows how elements produced on a wafer can be separated by means of an automated method at a larger spacing on an auxiliary carrier.

FIG. 1 shows different possible embodiments of components according to the invention in schematic cross section. According to FIG. 1a, a first housing part GT1 includes a flat circuit carrier, which can be used as a substrate for the arrangement of elements BE on this carrier and for placement of the second housing part GT2. The substrate has sufficient mechanical strength and includes at least one layer of an electrically insulating material. Preferred are multi-layer circuit carriers as shown in FIG. 1, which have at least one structured metallization plane between at least two dielectric layers DS1, DS2. On the bottom side of the substrate there are solderable contacts LK, which are connected by means of plated through-holes DK, and here also by means of metallization of the metallization plane, to the electrically conductive mountings HA. The mountings HA have a first region, which sits on the surface of the substrate. A second region away from this first region is arranged at a clear distance h above the surface of the substrate. Between the first and second regions, the mounting HA runs preferably non-linearly and is curved and/or angled and/or provided with slots. An electrical element BE is connected electrically and mechanically by means of its contact surfaces (not shown in the figure) to the second region of each mounting. Optionally, the connection is supported by an intermediate bonding agent, such as, for example, a solder bump (e.g., solder with Sn, Pb, Ag, or Au), stud bump (e.g., Au), solder tin, or the like. The connection can be effected by thermosonic or thermocompression methods. Conductive adhesives with isotropic or anisotropic conductivity, or combinations of all of the mentioned connection methods are also possible.

FIG. 1A: On the surface of the substrate, which here forms the first housing part GT1, sits a second housing part GT2, which as shown has a recess surrounded, for example, by an essentially uniformly thick material layer of the second housing part GT2. The recess is dimensioned so that the element, together with the mountings, has space in the recess without bumping against the cap. Preferably, the cap is metallic and, for example, is deep drawn or embossed and is fixed on the surface of the substrate with an arbitrary attachment method. Advantageously, the substrate has a metallic joint surface onto which the metallic or metal-coated cap is soldered, welded, bonded, or adhered. In the hollow space, which is formed under the cap and which is closed off by the substrate, a protective-gas atmosphere can be formed in order to protect sensitive structures of the element BE from moisture, corrosion, or oxidation. At least in this case and preferably also in other cases, the sealing of the cap to the substrate is hermetic, i.e., gas-tight and moisture-tight. Additionally or alternatively, for the harmless binding of existing moisture or harmful gaseous emanations, getter material can be introduced into the hollow space. The hollow space can also enclose a vacuum.

FIG. 1B shows another embodiment of the invention, in which the two housing parts form a flat circuit carrier as a base plate BP or substrate, a frame-shaped structure RS seated on this carrier, and a flat cover layer, which sits on this structure and forms the second housing part GT2. The substrate and frame structure form the first housing part. The frame structure is generated or deposited at a later time, but preferably before the installation of the element BE on the substrate. The flat layer of the second housing part GT2 sits on the frame structure and is connected to the frame structure directly, or with the help of a sealant or soldering agent (not shown in the figure). The substrate forming the housing base can be selected as in the first embodiment. The frame structure is produced from a separate material that is preferably different from that of the substrate. For the second housing part GT2, that is, the cover layer, in principle the same materials selection as that for the substrate applies. However, because a covering function is given to the second housing part GT2 exclusively, without requiring structuring, the second housing part preferably has a one-layer, metallic, or optionally metal-laminated construction. For example, 50 to 100 μm thick metal foils made from copper, nickel, or Kovar, and also metallized plastic films, are possible.

The frame structure is preferably metalized at least at the joint surface at which the second housing part sits on the frame, so that soldering and welding are possible as bonding methods. The second housing part or the frame structure can be coated with a thin soft-solder layer at least in the joint region. Advantageously, the soft solder has a relatively high solidification point of, for example, significantly over 260° C., in order to prevent remelting of the solder connection when soldering the completed component into an electronic circuit. In addition to lead-containing solders, which, however, should be increasingly avoided, primarily alloys such as AuSn or glass solder are to be used.

Alternatively, a hard solder, by definition, with a high softening point of at least 450° C. can be used, and can be melted advantageously through local heating in the region of the joint surfaces, e.g., by means of thermodes or focused radiation or lasers.

A third possibility consists in diffusion soldering, in which a low melting point solder (e.g., a tin layer only a few μm thick) reacts almost completely with the metallic joint surfaces (e.g., made from Cu) under formation of high melting point inter-metallic phases, e.g., Cu₃Sn. It is thus possible to produce a connection of the two housing parts that is temperature-resistant up to, e.g., 600° C., despite moderate temperatures of, e.g., 300° C., and that therefore no longer melts in later processes.

Mountings and the element, as well as the mutual attachment, are constructed accordingly as in FIG. 1a.

FIG. 1c shows a third embodiment in which the first housing part GT1 is made from a solid, optionally monolithic material, so that a recess arranged on the top side can hold an element BE together with mountings HA. In FIG. 1c, a construction with a first housing part GT1 is shown, which has plated through-holes DK only in the region of the base. However, it is also possible to produce the first housing part from several dielectric layers, in which structured metallization layers are integrated at least in the base region. In this case, the plated through-holes can be offset relative to each other by the individual dielectric layers, as was already shown with reference to FIGS. 1a and 1b. The mountings HA can be installed on the base of the recess directly onto the surface of the first housing part GT1. It is also possible, however, to provide metallic connection surfaces directly on the base or the surface of the first housing part within the recess under the mountings. The cover layer forming the second housing part GT2 can be constructed as described in FIG. 1b.

FIG. 1d shows a fourth embodiment, which represents a modification of FIG. 1b (2nd embodiment). This component also includes a substrate that forms the base plate BP of the housing, a frame structure RS sitting on this base plate, and a cover plate that sits on this structure and forms the second housing part GT2. In contrast to FIG. 1b, however, here the mountings sit on connection surfaces AF which sit on the substrate, but which are guided out from the recess underneath the frame structure. These connection surfaces are connected to solderable contacts LK arranged on the bottom side of the substrate, first outside of the hollow space by means of plated through-holes or by means of conductor tracks that run past the outer edge of the substrate to its bottom side. Such a substrate has all of the advantages of a one-layer circuit carrier, in particular, simple production and the possibility of hermetic closure.

Components according to the invention can also have several elements BE in the recess, of which at least one is sensitive to stress with respect to its element functions. The element can have sensitive element structures, which for SAW and BAW elements are preferably arranged on the surface of the element chip facing toward the bottom housing part GT1. The element can also carry inner structures or element structures on the surface facing toward the second housing part GT2.

In particular, it is possible in this last case to provide, for the constructions according to FIGS. 1b, 1c, and 1d, a second housing part GT2 that is transparent to radiation, so that a radiation-sensitive or radiation-emitting element can be encapsulated in the housing. Furthermore, it allows a transparent housing part to act on an encapsulated element with radiation, in order to change structures. In this way, optional electrical connections can be separated or an element can be trimmed. This can be effected, in particular, through material ablation by means of a laser emitting radiation through the cover layer. In principle, however, it is also possible to introduce energy by means of a laser beam that is suitable for material transport, in order to redeposit the material at a different position.

In the following, the production of a component according to the first embodiment is explained with reference to FIG. 2, which shows the various steps during the process. The starting point is a large surface area circuit carrier, here a multi-layer substrate BP, which has inner metallization layers and plated through-holes DK with which contact surfaces KF on the surface are connected to solderable contacts LK on the bottom side. The substrate is, in particular, a substrate wafer or a large surface area substrate on which a plurality of elements can be mounted one next to the other in order to generate an appropriate or smaller number of components through later division of the substrate wafer or separation of the components.

In the first step, a sacrificial layer OS is deposited on the substrate BP as a whole surface layer, preferably in the form of a varnish, by means of centrifuging, casting, immersing, or spraying. A dry film can also be laminated.

In the next step, the sacrificial layer OS is structured, for example, by means of phototechnology through direct or indirect structuring or by means of laser ablation. The structuring is performed such that corresponding layer regions of the sacrificial layer can remain at the points where the mountings later run at a distance from the surface of the substrate. For scanning exposure or laser ablation, previously detected warping of the substrate, as occurs in particular in sintered ceramics that often lose their dimensional accuracy during sintering, can be taken into account and compensated. A photoresist as a sacrificial layer OS can be structured, for example, through development. FIG. 2A shows the arrangement on this processing step.

In the next step, the mountings are generated, in that initially metallization is deposited over the entire surface on free, exposed surfaces of the substrate and sacrificial layer OS, and then structured. For deposition, wet-chemical deposition, PVD, sputtering, or vaporization are suitable processes. Then this metallization can be reinforced by galvanic or electroless means. As materials for the metallization of the mounting, for example, copper, nickel, chromium, aluminum, titanium, silver, or palladium in a thickness of 1-50 μm is suitable. Optionally, an adhesive layer with a thickness of less than 1 μm can still be applied under the metallization, for which, for example, titanium, zirconium, hafnium, tungsten, or chromium is suitable. It is advantageous, for example, to apply the adhesive layer over the whole surface and then to structure it and to reinforce the structured adhesive layer galvanically. It is also possible to deposit a resist on a whole surface base layer and to generate the metallization through galvanic molding of a resist structure by reinforcing the base metallization exposed in the resist openings. After removal of the resist structure the again exposed base metallization is removed by etching.

The structuring of this metallization is effected such that a non-linear or slotted and especially a band-shaped section is produced between a first region of the metallization, which lies on a connection surface AF on the substrate top side, and a second region, which runs on the surface of the sacrificial layer OS. The structuring can also be effected such that a non-linear shaped section, such as a bridge, runs over a layer region of the sacrificial layer, wherein both ends of the section are connected to the substrate surface or a contact surface.

The dimensioning of the mountings can lie in the range of the conductor tracks in use, which have, e.g., a width of 10 to 200 μm for a thickness of 1 to 50 μm. For example, a quartz chip with dimensions of 2×1×0.1 mm³ that is typical for resonators as example elements has a mass of ca. 0.5 mg. For this chip, four to six mountings can be provided, wherein it is also possible to provide mountings without corresponding electrical connections for only purely mechanical attachment. If an acceleration of 10,000 G acts on such a component, then for each connection a force acting on the connection is produced on the order of 10 mN. Such loads are absorbed without a problem by suitably dimensioned connections of the described type.

Then a solder mask LM can be deposited selectively, with which the wetting property of the metallization relative to the solder is generated and thus a later solder point can be defined. FIG. 2B shows the arrangement on this processing step.

In the next step, an element chip BE is set on the structured mountings and fixed by soldering. For this purpose, the element chip already has prefabricated solder or stud bumps BU, with which it is set on the prefabricated second region of the mountings, above its contact surfaces. It is also possible to deposit these solder or stud bumps on the second regions of the mountings HA lying on the sacrificial layer OS. FIG. 2C shows the arrangement during placement. Alternatively, the element can also be attached to the mountings with conductive adhesive.

For the production of the housing on the wafer plane, it is advantageous to mount the desired number of elements to be installed on the substrate or the mountings on this substrate in advance, in an arrangement corresponding to the pattern of recesses in an auxiliary carrier. The auxiliary carrier is then placed with the elements on the substrate in such a way that the elements are arranged in the recesses in the mountings. As an auxiliary carrier, for example, an adhesive film can be used.

The elements fixed on the auxiliary carrier are then connected electrically and mechanically to the mountings. Then the auxiliary film can be removed.

For elements operating with special precision, such as the mentioned frequency-determining elements, for example, high-precision resonators, it is possible to test the electrical function of the element in a processing step before placing the second housing part. As a function of a test result deviating from the desired value, a trimming process can then be performed in which the properties of the element can be changed, in particular, by depositing or removing material, and can be adapted to the desired value. For removing material, in particular, ion-beam etching is suitable.

In the next step, the sacrificial layer OS is removed. This can be effected by means of solvent. Preferably, however, the sacrificial layer includes a material that can be thermally transformed into the gaseous state to more than 99.9 mass percent through decomposition, oxidation, vaporization, or sublimation. For example, for this purpose, polymers from the class of cyclic polyolefins are suitable and, for example, a sacrificial layer made from such materials is volatized by heating to a temperature of less than 300° and preferably to less than 180° C. Suitable connections that decompose completely into gaseous products belong, e.g., to the substance class of polynorbornenes. The heating can be performed as a separate step. However, it is also possible to perform the soldering of the element chip by means of reflow soldering at an appropriate temperature, wherein the solder connections are generated and the sacrificial layer is removed simultaneously. FIG. 2D shows the arrangement, in which the second regions of the mountings HA are now arranged at a clear distance above the surface of the substrate such that a gap of ca. 1 to 50 μm remains. This corresponds approximately to the generated thickness of the sacrificial layer. Here it is advantageous if the temperature for volatization of the sacrificial layer does not harm the strength or stability of all of the other elements created on the component at this point in time, that is, all of the other melting and decomposition temperatures lie above the decomposition temperature of the sacrificial layer.

In the next step, a second housing part GT2 provided with a recess, in particular, a prefabricated metallic cap that has a sufficiently large recess for the formation of a hollow space, is set and mounted on the substrate. If the second housing part includes a metallic layer at least on the bottom side or is made completely from metal, then a soldering process can be used for attachment with another metallization WM on the base plate BP. However, it is also possible to weld a metallic cap, with appropriate metallization applied in the region of the joint surfaces, on the substrate surface. FIG. 2E shows the completed element.

It is also possible to completely eliminate solder, adhesive, or sealing agent if the surfaces of the two housing parts themselves can enter into a connection, for example, in a wafer bonding method. The additional possibility is provided to connect the two housing parts with a so-called wringing technology. Here, the additional sealing agent can also be eliminated. All that is required is to form the joint surfaces sufficiently smooth.

The production of a component according to a second embodiment is explained with reference to FIG. 3. In the two first steps, a circuit carrier BP used as a substrate in the first embodiment is provided with a structured sacrificial layer OS, above which a metallization is generated and structured that corresponds to future mountings HA. In contrast to the first embodiment, now a frame structure RS is generated on the surface of the substrate, for example, galvanically and especially through galvanic forming. For this purpose, the circuit carrier BP can already be provided by the manufacturer with correspondingly structured base metallization GM, which is then made thicker only for the frame structure. FIG. 3C shows the first housing part completed in this way with the substrate and the frame structure RS deposited on this substrate.

In the next step, an element chip BE is set on the second regions of the mountings HA (FIG. 3D) as in the first embodiment and connected to these mountings. The connection can be realized as described above with reference to FIG. 2. By means of a preferably thermal step, the sacrificial layer OS is then removed, wherein the second regions of the mountings HA are arranged at a distance above the surface of the substrate BP while leaving an air gap. The element BE is connected to the substrate exclusively by means of the mountings, wherein the mountings are designed to absorb plastic and/or elastic deformations.

FIG. 3F: the metallic frame structure RS can now be covered and mechanically connected, for example, by means of a solder layer including tin between the frame structure and second housing part GT2, to a second housing part that includes at least one metallic layer and has a flat construction. This solder layer LS can be, e.g., 10 μm thick and can include an Sn layer.

Because both the substrate BP and also the second housing part GT2 or the cover used for this purpose preferably have a large surface area and include several hollow spaces or components, in the last step the components are separated, wherein cuts are made in the housing parts from one or two sides such that the hollow spaces remain sealed. Separation of the sealed housing made on the wafer plane can be realized through sawing, through laser structuring, or through fracturing.

FIG. 4 shows the production of an element according to a fourth embodiment in which, by contrast to the first and second embodiment, a substrate with a prefabricated recess is used, which forms the first housing part GT1. This has the consequence that the sacrificial layer OS and the mountings HA that can be structured in this way must be generated within the recess. The base plate BP and side walls SW of the first housing part GT1 are preferably made from the same dielectric material. Together with production of the mountings, metallization FM can be deposited at least on the region of the surface forming the joint surface that surrounds the recess like a frame. The metallization can also cover parts of the inner wall and the base of the recess, as shown, e.g., in FIG. 4F. The placement of the element chip and the removal of the sacrificial layer are performed as explained in the other examples. The second housing part GT2 is selected and installed as in the second embodiment. FIG. 4F shows a substrate in which the metallization is deposited both on the joint surfaces and also on the inner walls, and partially on the base of the recess. Here it is possible to electrically isolate the metallization FM on the joint surfaces from the metallization on the inner surfaces of the side wall, as shown in FIG. 4F at the right (case b). On the left (case a), the metallization in the region of the joint surfaces and side wall has a one-piece or uninterrupted construction.

If the connection of the first and second housing part is realized by means of soldering, then it is advantageous to separate the metallization on the joint surfaces and inner sides of the recess as shown in FIG. 4F at the right as case b, or to provide a stop layer that cannot be wetted with solder at the junction, in order to hold the solder in the connection region of the joint surfaces while connecting the first and second housing part by means of solder, and to prevent leakage out of this region.

An at least partially metallic lining of the inner space of the recess allows this side wall bounding the recess to be made from a material that is gas-permeable or moisture-permeable from the inside out. High-quality sealing can be realized via the metallization, with which the boundary surfaces between the side wall (frame structure) and substrate (base plate) of the first housing part GT1 can also be sealed.

The metallization is also advantageous for a construction in which the frame structure is bonded to the substrate. The metallization can also be deposited at least partially by means of a PVD process, such as sputtering or vaporization. Advantageously, PVD methods are combined with galvanic or electroless metal deposition processes. A bottom-most layer used as an adhesive layer can include, e.g., 50 nm Ti and above this 200 nm Cu.

Mountings, metallic frame structures, and/or metallic linings of the hollow space can best be made economically in the desired layer thickness by means of electroplating. For economical and/or technical reasons, different material thicknesses and/or different metals for different function elements can be preferred, e.g., a common base metal with different surface coatings. It is therefore advantageous to form the connections required for electroplating in such a way that separate galvanic steps can be performed for different function elements. In this way it is avoided, e.g., that metal layers required only for certain function elements (e.g., an Au coating for stud bumps) are also generated for other function elements.

In another advantageous variant of the invention for the production of the component, the sacrificial layer is removed after production of the mountings before the element is set on the mountings and connected to these mountings. A durable electrical and mechanical connection between the element and mountings can also be achieved after removal of the sacrificial layer, in that the second regions of the mountings, which are provided for connection to the element and are at a distance h from the base of the recess, are pressed onto the base by the set-down pressure until the connection is produced. For this purpose, the elastic deformability of the mountings is used, which then return to their original position or shape after connection to the element, so that the bonded element is arranged at the corresponding desired distance h from the base of the recess and thus from the lower first housing part. For this variant, thermosonic bonding can be used as the bonding method.

In FIG. 5, a method is shown, with which parallel element chips generated in one element wafer can be separated advantageously such that an arrangement fixed in advance is obtained for the elements, with suitable element spacing or in a suitable pattern. For this purpose, the element wafer is bonded with the reverse side, which has no electrical connections, onto an auxiliary carrier HF, preferably on a so-called UV release film. Then the element wafer is sawed through from the front side, without cutting through the film.

In a UV release film, the adhesion can be greatly reduced and practically eliminated by means of UV effects. This is now used to advantage, in that the elements bonding to such an auxiliary film HF are bonded with the element front side on another auxiliary film. Here, the adhesion of desired elements is canceled through targeted radiation on the reverse side of the UV release film. By stripping the auxiliary film, those chips whose adhesion to the UV release film was reduced, can now be transferred to the second auxiliary film.

In this way it is possible in one step to bond only chips spaced apart from each other onto a second auxiliary film, as shown in FIG. 5. If one selects a pattern in which in one step every second element in both the X-direction and also in the Y-direction is transferred, then the dense packing of elements on the element wafer can be transferred in four steps to four arrangements or to four auxiliary films in which only a quarter of the original element density exists with corresponding spacing in the X-direction and Y-direction. The spacing produced in this way between the elements bonded onto the second auxiliary film can be sufficient to use the second auxiliary film with the elements directly in the method shown in FIG. 5. However, it is also possible to deposit the elements bonded on the second auxiliary film at an even greater spacing with the described separation method, wherein with this method the distance can be set only in a whole-number multiple of the element width. If this is not favorable for the dimensioning of the housing parts, then the elements can be arranged individually on an auxiliary film in the desired pattern.

If different elements are installed in a common housing, then the different elements can be assembled in the same or a similar way on a common auxiliary carrier. If necessary, the described separation process with increased pattern spacing can be performed separately for each element type. The combination of the different elements on a common auxiliary carrier is then performed for the first time in the last step.

Another preferred possibility for separation also takes advantage of two steps, wherein cuts are made into the element wafer from the front side of the elements in a first step. The element wafer is then applied with the front side onto an adhesive film or an auxiliary carrier and ground away from the reverse side until the cuts are exposed, and the individual elements are thus separated. Then the elements are moved with the reverse side, for example, onto the mentioned release film. The processing steps are controlled in such a way that the elements lie on the auxiliary carrier last used in the process with the back side facing the contact surfaces.

The invention is not limited to the embodiments and the figures shown. Instead, the specially constructed mountings can be combined with nearly all known hollow-space housings. In this way, a stress-free installation of the element is always achieved, so that the element can be operated reliably without unacceptable changes to the element properties even under strong thermal and mechanical load cycling. The proposed component is not limited to a certain element type, and allows the miniaturized housing of a plurality of a variety of chips, in particular even those with high sensitivity to mechanical stress. The invention further opens up the possibility of hermetic sealing, which reliably prevents the penetration of gases, moisture, or chemicals. The protection of the elements is supported by providing a protective-gas atmosphere within the hollow space. Furthermore, an element housing can be obtained which is completely free from organic materials in the interior, since all elements remaining within the hollow space can be of an inorganic nature. Thus, contamination-sensitive element chips can be protected from out-gassing constituents.

In all of the methods according to the invention for producing the components, the sacrificial layer can be used for structuring the mountings, wherein regions detached from the substrate surface or arranged at a distance above this surface are used. In addition, the bonding of the elements is supported at these mentioned regions by the sacrificial layer when bonding is performed before the removal of the sacrificial layer. The detached regions of the mountings are here supported by the sacrificial layer arranged underneath. In the processing, different metallization steps can also be used for the simultaneous generation of mountings and metallization on such housing parts as are used for improving the joint surfaces or for shielding the recess or the entire component. Also, for the production of a metallic frame structure, metallization methods can be used alternatively and simultaneously for the production of other metallization layers of the component. With the proposed component, it is also possible to use a housing platform for a plurality of different elements and in particular MEMS elements, for which housings adapted specifically to the element have been required up until now. This leads to an economical platform for practically all comparable products.

### LIST OF REFERENCE NUMERALS

BE Mechanically sensitive element, chip
GT1, GT2 Housing parts
HA Mountings
DM Sealing means, e.g., adhesive
HT Auxiliary carrier
KF Contact surfaces on chip
AF Connection surfaces on substrate
DK Plated through-holes
LK Solderable (outer) contacts
FM Joint surface metallization
MS Metallization layer
h Height of air gap
WM Additional metallization
BU Bump
BP Base plate, substrate
LM Solder mask
OS Sacrificial layer
GM Substrate metallization on joint surface
RS Frame structure
LS Solder layer

1. A device having a hollow space for a mechanically sensitive electrical element, the device comprising:
a first housing part; and
a second housing part rigidly connected to the first housing part via joint surfaces, and
connection surfaces on a base of a recess in the first housing part the first housing part being covered by the second housing part to form an enclosed a hollow space, wherein
the mechanically sensitive electrical element comprises a chip having contact surfaces on a surface, and
the mechanically sensitive electrical element is suspended in the hollow space by electrically conductive mountings configured to deform elastically or plastically, the electrically conductive mountings connecting at least one of the contact surfaces to at least one of the connection surfaces.

2. The device of claim 1, wherein the mountings have an expansion reserve and are configured to elastically or plastically absorb tensile and compressive stresses.

3. The device of claim 1, wherein the mountings have a non-linear profile and are bent, angled or slotted.

4. The device of claim 1, wherein the chip comprises electrical contact surfaces on a surface configured to electrically and mechanically connect the chip to the electrically conductive mountings.

5. The device of claim 1, further comprising plated through-holes electrically connecting the connection surfaces to solderable contacts on an outer side of a housing part.

6. Thee device of claim 1, wherein:
the mountings have first and second regions and a longitudinal extent parallel to the base of at least one of the housing parts between first and second regions,
the mountings are each connected by the first region to the electrical connection surfaces on the base,
the mountings each extend toward the second region above the base,
the element is connected by contact surfaces to the second region to form an air gap between the base and the second region.

7. The device of claim 6, wherein the base of the housing part comprises a multi-layer circuit board, comprising plated through-holes that connect the connection surfaces to solderable contacts on the opposite surface.

8. The device of claim 1, wherein the housing part with the recess comprises:
a base plate;
a frame extending above the base plate, and
the second housing part comprises a flat cover layer on the frame.

9. The device of claim 8, wherein the base plate comprises connection surfaces, plated through-holes, and solderable contacts.

10. The device of claim 8, wherein at least a surface of the frame comprises a metal.

11. The device of claim 9, wherein base plate and second housing part each include, one or more of ceramic, LTCC, HTCC, glass, silicon, plastic, liquid-crystalline polymer, a conductor plate laminate, or another circuit carrier.

12. The device of claim 8, wherein the cover layer and base plate are composed of the same material.

13. The device of claim 8, wherein the frame comprises a metallized surface area toward the hollow space.

14. The device of claim 13, wherein the base plate comprises a metallized plate in a peripheral region within the frame, having the metallization that extends continuously from the peripheral region past the inner side of the frame and past the top side of the frame forming a joint surface.

15. The device of claim 8, wherein the cover layer comprises a metal foil or a plastic film coated with metal.

16. The device of claim 1, wherein one of the first and second housing parts comprises a base plate and includes the connection surfaces, plated through-holes, and solderable contacts, wherein the housing part with the recess comprises a metallic cap on the base plate.

17. The device of claim 1, wherein the first and second housing parts are connected at the joint surfaces by glass solder, solder, an adhesive layer, or directly through welding.

18. The device of claim 1, wherein the element comprises a SAW chip, a BAW chip, or a MEMS element.

19. The device of claim 1, wherein the element comprises a frequency-precise or frequency-determining element and includes a resonator in MEMS, SAW, or BAW technology.

20. The device of claim 1, wherein a total number of mountings is greater than a total number of electrical connections and the additional mountings are configured to provide a purely mechanical connection between the element and housing part.

21. The element of claim 1, further comprising a mechanically rigid connection between the element and one of the first and second housing parts, the connection having a cross section that is small relative to the surface area of the element chip.

22. The device of claim 1, wherein the hollow space comprises a hermetically encapsulated space having no organic materials in the interior of the encapsulated space.

23. The device of claim 1, wherein the device consists essentially of materials having a melting point greater than or equal to 260 C.

24. A method for producing a device with a hollow space for a mechanically sensitive electrical element, the method comprising:
preparing a first housing part and a second housing part such that the first and second housing parts match each other at joint surfaces and are shaped so that a hollow space is enclosed between the first and second housing surfaces when the first and second housing parts are connected at the joint surfaces, and
forming solderable contacts on an outside of the first housing part.
connecting the solderable contacts by plated through-holes to contact surfaces on a base of the first housing part facing the hollow space,
applying and structuring a sacrificial layer on the base of the first housing part,
applying a structured metal layer to form mountings the mountings having a first region connected to the contact surfaces and a second region remote from the first region on the structured sacrificial layer,
placing and connecting an element to the second regions of the mountings, and
removing the sacrificial layer form an air gap between the second region of the mountings connected to the element and the base of the first housing part.

25. The method of claim 24, further comprising:
placing the second housing part on the first housing part; and
producing a tight connection between the first and second housing parts.

26. The method of claim 24, wherein:
preparing the first housing part comprises forming a plurality of recesses in a first large surface area housing part wafer;
preparing the second housing part comprises providing a second large surface area housing part:
applying the structured metal layer to form the mountings comprises generating the mountings for all of the plurality of recesses in the first large surface area housing part wafer in a common processing step,
placing and connecting the element to the second regions of the mountings comprises inserting elements into the plurality of recesses of the first housing part wafer and attaching the elements to the mountings,
and the method further comprises connecting the first housing part wafer to the second large surface area housing part enclosing the elements in the recesses, and
separating the connected housing part and housing part wafer into components with individual or with groups of hermetically enclosed elements.

27. The method of claim 24, further comprising installing the elements in an intermediary step in the alignment with the reverse side opposite electrical contact surfaces on an auxiliary carrier, and
removing the auxiliary carrier after connecting the elements to the mountings.

28. The method of claim 24, further comprising applying structured metallization layers on the surfaces of the housing part wafer or elements as mountings.

29. The method of claim 24, further comprising reinforcing the mountings by a polymer layer, above or below the mountings.

30. The method of claim 24, further comprising, after the placement and connection of the elements to the mountings and before the placement of the second housing part, electrically testing the element and based on a result of the testing, performing a trimming process to modify properties of the element by depositing or removing material.

31. The method of claim 24, wherein the sacrificial layer comprises an organic layer configured to decompose thermally without forming a solid residue.

32. The method of claim 24, further comprising performing a soldering or bonding process to connect the elements to the first housing part by means of the mountings.

33. The method of claim 24, further comprising:
generating the sacrificial layer and mountings above the front side of the element carrying the contact surfaces,
placing the elements with the sacrificial layer and mountings on the connection surfaces, and
removing the sacrificial layer to form an air gap between the ends of the mountings connected to the element and the base of the first housing part.

34. The method of claim 24, further comprising suspending two or more equivalent or different elements on mountings in the same hollow space in a housing part.
